(19) United States
(12) Patent Application Publication
(10) Pub. No.: US 2026/0074498 A1
(43) Pub. Date: Mar. 12, 2026

(54) Electrical Outlet Cover

(71) Applicant: Grease Armor USA, Inc., Cambridge, MD (US)

(72) Inventor: James Fabiszewski, Cambridge, MD (US)

(73) Assignee: Grease Armor USA, Inc., Cambridge, MD (US)

(21) Appl. No.: 19/394,261

(22) Filed: Nov. 19, 2025

Related U.S. Application Data
(63) Continuation-in-part of application No. 18/382,170, filed on Oct. 20, 2023, now Pat. No. 12,483,017.
Application No. 18/382,170 is a continuation of application No. 18/209,832, filed on Jun. 14, 2023, now Pat. No. 11,811,208.

(51) Int. Cl. H02G 3/14; H01R 13/447; H05K 5/02

(52) U.S. Cl. CPC H02G 3/14; H01R 13/447; H05K 5/0247

(57) ABSTRACT

A faceplate unit for use with an electrical receptacle includes a planar body configured for mounting to the receptacle using one or more fasteners. An integrally formed mounting bracket is located on a top side of the planar body and includes an offset portion extending along the length of the faceplate. The offset portion is configured to engage a complementary structure to facilitate secure and removable attachment. The faceplate unit may further include features such as safety posts and environmental seals to enhance protection against contaminants and improve installation stability.

### CROSS-REFERENCE TO RELATED APPLICATIONS

This application is a continuation-in-part of pending U.S. application Ser. No. 18/382,170, filed on Oct. 20, 2023, which is a continuation of pending U.S. application Ser. No. 18/209,832, filed on Jun. 14, 2023, now U.S. Pat. No. 11,811,208, the entire disclosures of which are incorporated herein by reference.

### TECHNICAL FIELD

The present disclosure relates to the field of safety covers for electrical outlets and, more specifically, to an outlet cover assembly for electrical outlets located near grease splatter source in commercial kitchens.

### BACKGROUND

Commercial kitchens produce airborne grease contaminants during cooking operations involving fats or oils, leading to safety hazards, reduced productivity, and equipment failures. These contaminants, released into the kitchen environment, pose significant challenges to maintaining safe and efficient operations.

The outlet cover assembly described herein, constructed from durable materials such as solid stainless steel, enhances safety and mitigates equipment failure risks that can result in revenue loss and costly service repairs. When installed, the outlet cover unit shields the electrical connection and disconnection points of kitchen equipment from grease contamination and deterioration. This protection reduces the risk of flash grease fires, electrical shocks, and personal injuries caused by grease buildup. Additionally, the assembly safeguards these electrical points from water and cleaning chemicals, such as degreasers, commonly used during periodic or nightly kitchen cleaning processes, including power washing.

The outlet cover assembly comprises an outlet cover unit and a faceplate mounting bracket, which replaces the standard electrical outlet faceplate typically installed over wall-mounted receptacles to cover exposed wiring and provide a polished appearance. The faceplate mounting bracket includes an offset portion designed to securely and removably attach the outlet cover unit via a lip portion, eliminating the need for a separate wall-mounted bracket. This design simplifies installation and reduces the risk of damaging hidden infrastructure, such as electrical wiring, gas lines, or water pipes, during installation.

No existing product adequately addresses grease contamination and deterioration in commercial kitchens. The proposed outlet cover assembly, designed with solid stainless steel to match commercial kitchen standards for material, thickness, strength, and cleanability, provides an optimal solution. This robust design enhances safety, protects equipment from grease-related failures, and ensures compatibility with the rigorous demands of commercial kitchen environments.

### SUMMARY

In one embodiment, an outlet cover unit comprises an upper section with a lip portion and a top portion, a front section connected to the top portion, a right-side section, and a left-side section, both attached to the front and upper sections. The lip portion extends downward, substantially parallel to the front section. The right-side section is planar, defined by a bottom side, front side, back side, and top side. Similarly, the left-side section is planar, defined by corresponding bottom, front, back, and top sides. An open end, opposite the front section, is formed by the lip portion, the right-side back side, and the left-side back side. The top portion of the upper section slopes downward from the open end toward the front section.

The outlet cover unit may further include a bottom section connected to the front, right-side, and left-side sections, further defining the open end. An opening in the bottom section may be provided to allow passage of an electrical cord into the outlet cover unit.

In another embodiment, the bottom section comprises a bottom left section and a bottom right section. The bottom left section connects to the front and left-side sections, and the bottom right section connects to the front and right-side sections. A gap between the bottom left and bottom right sections allows passage of an electrical cord, with the open end further defined by these bottom sections.

The outlet cover unit is designed to integrate with a faceplate mounting bracket tailored for environments prone to grease and other contaminants, such as commercial kitchens or workshops. The faceplate features a planar body that overlays and secures to a standard electrical outlet receptacle, with one or more apertures aligned with the outlet's socket openings to accommodate electrical plugs without requiring modifications to the electrical box or wall.

The faceplate includes an integrated mounting bracket extending outward from the planar body near the apertures. This bracket is configured to releasably engage the lip portion of the outlet cover unit, enabling secure and removable attachment. When attached, the outlet cover unit encloses an inserted electrical plug, preventing grease, liquids, or other contaminants from entering the outlet openings.

The faceplate may incorporate two safety posts positioned above the socket openings, extending outward from the planar body. These posts prevent the outlet cover unit from resting on the electrical plug prongs or the faceplate's planar surface, ensuring proper attachment to the mounting bracket.

The faceplate is designed to accommodate standard single- or multi-gang outlet configurations and various receptacle types, including those for 220V devices, with adaptable aperture configurations.

The faceplate and outlet cover assembly offer: (i) rapid, tool-minimal installation without wall penetration; (ii) robust stainless steel construction for enhanced durability and protection; and (iii) integrated safety posts to prevent contact between the outlet cover unit and energized plug prongs. This design complies with safety standards (e.g., NEC Article 406 for receptacle plates) and extends the operational life of electrical devices in high-moisture or corrosive environments.

The features and advantages described herein will be further apparent from the detailed description and accompanying drawings. The disclosed embodiments extend to those within the scope of the patent claims, whether or not they include all the advantageous features described.

### BRIEF DESCRIPTION OF DRAWINGS

The present system is illustrated by way of example and not limited to the figures of the accompanying drawings in which like reference numerals indicate similar elements.

FIG. 1 is an isometric view (from the back) of an electrical outlet cover and bracket, in accordance with an embodiment of the present disclosure.

FIGS. 2A, 2B, 2C, 2D, and 2E are a top view, bottom view, front view, left-side view, and right-side view, respectively, of the electrical outlet cover of FIG. 1.

FIG. 2F is an isometric view of the electrical outlet cover taken along line 2F-2F of FIG. 2C.

FIG. 3 is an isometric view of a hanging bracket, in accordance with an embodiment of the present disclosure.

FIGS. 4A, 4B, and 4C are a front view, top view, and side view of a faceplate with integrated mounting bracket and safety posts, in accordance with an embodiment of the present disclosure.

FIG. 4D is an isometric view of a faceplate with integrated mounting bracket, in accordance with an embodiment of the present disclosure

FIG. 5 is an isometric view of an electrical outlet cover and a faceplate with integrated mounting bracket, in accordance with an embodiment of the present disclosure.

### DETAILED DESCRIPTION

Identically numbered reference characters across the drawings correspond to the same elements, and duplicative descriptions of each reference character may be omitted for clarity.

The present invention may be embodied in various forms. The illustrative embodiments described herein are examples of the invention's principles and are not intended to limit the invention to the specific embodiments described or illustrated.

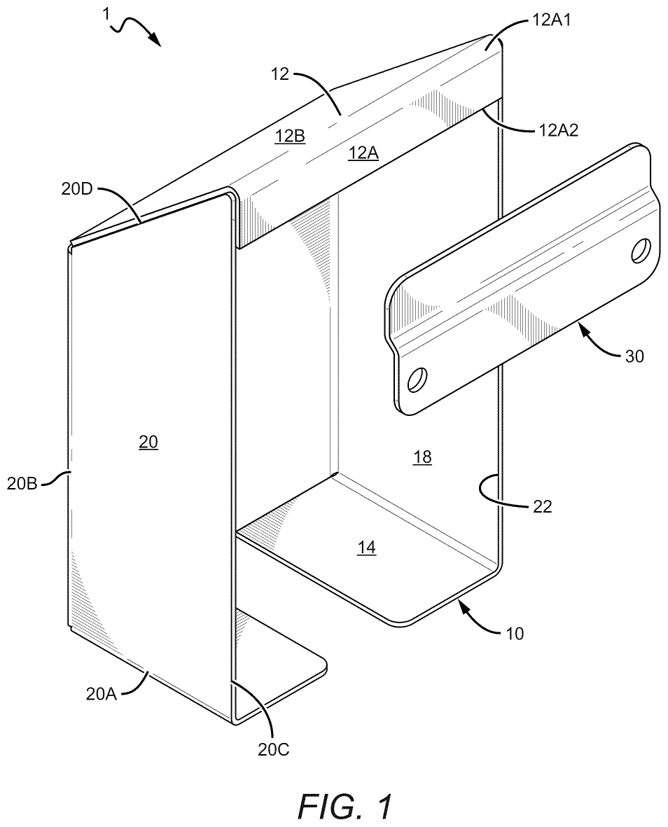

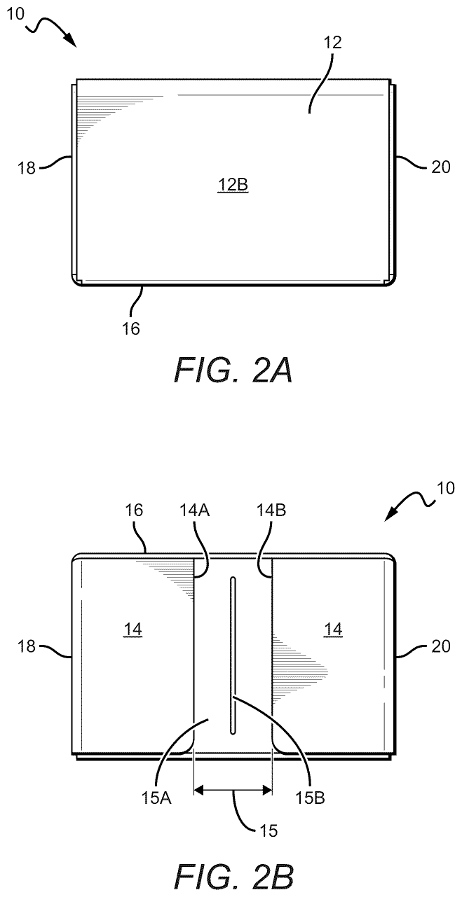

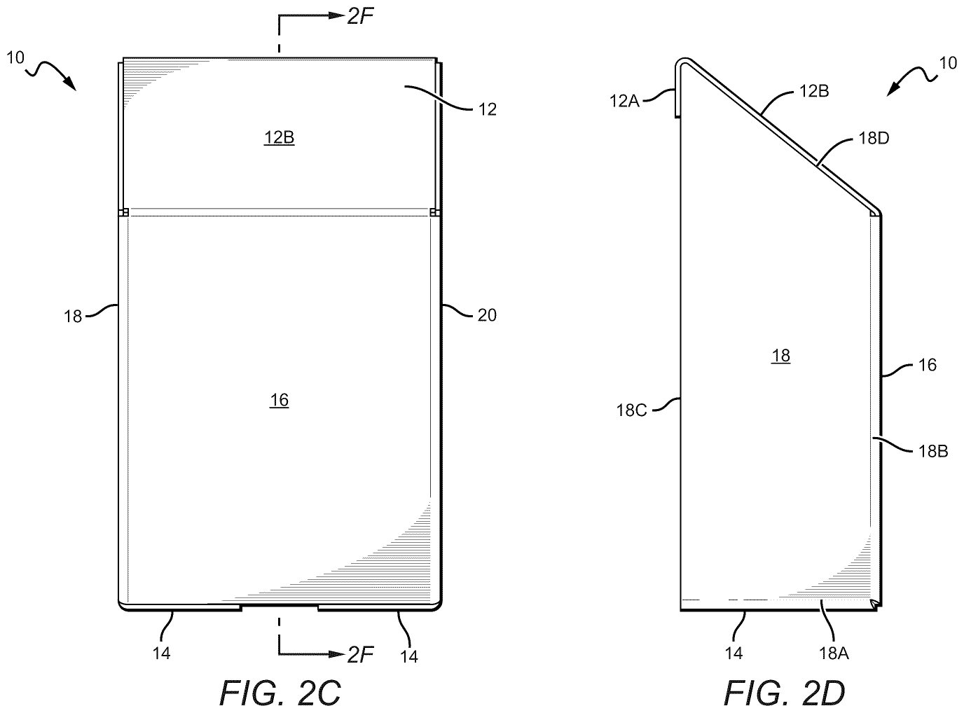

Referring to FIGS. 1 and 2A-2F, an outlet cover assembly 1, comprising an outlet cover 10 and a mounting bracket 30, is designed for application to an electrical wall outlet (not shown). The outlet cover 10 forms a protective enclosure around the electrical outlet (e.g., one or more receptacles for receiving a plug, not shown) to prevent ingress of contaminants, such as grease, liquids, or other foreign objects, in environments like commercial kitchens.

The outlet cover 10 consists of an upper section 12, a bottom section 14, a front section 16, a left-side section 18, and a right-side section 20 opposing the left-side section. These sections may be integrally formed or welded together to create the outlet cover 10, defining an open end 22 opposite the front section 16 to allow access to the electrical outlet. The outlet cover 10 may be constructed from materials such as polymer, metal, or stainless steel, for example, 16-gauge type 304 stainless steel conforming to ASTM A240.

The upper section 12 includes a lip portion 12A and a top portion 12B. The lip portion 12A extends downward, substantially parallel to the front section 16, from a first end side 12A1. The open end 22 is defined by a second end side 12A2 of the lip portion 12A, the bottom section 14, and the back sides of the left-side and right-side sections 18 and 20. The second end side 12A2 is configured to engage a separate mounting bracket 30 or faceplate 300 (described below).

The top portion 12B extends from the first end side 12A1 of the lip portion 12A to a second end side 12B1 at the front of the outlet cover 10. The left-side section 18 mirrors the right-side section 20, each having a planar shape with four sides: a bottom side 18A (20A), front side 18B (20B), back side 18C (20C), and top side 18D (20D). The front side 18B (20B) connects to the front section 16, and the bottom side 18A (20A) connects to the bottom section 14.

The front and back sides 18B, 18C (20B, 20C) extend generally perpendicular and upright from the bottom side 18A (20A). The front side 18B (20B) is shorter than the back side 18C (20C), causing the top section 12 to slope downward from the open end 22 toward the front section 16. For example, the front side 18B (20B) may be 5 inches tall, the back side 18C (20C) 7 inches tall, and the bottom side 18A (20A) 2.5 inches long (defining the depth of the outlet cover 10). This sloped design prevents liquid contaminants from pooling on the outlet cover 10, facilitates their removal, and discourages placing items on top of the cover, unlike a flat surface. The upper section 12 may include grooves or a slick coating to further enhance contaminant removal.

The bottom section 14 comprises a bottom left section 14A and a bottom right section 14B, forming a gap 15 between them. The left and right sections 18 and 20 may be spaced 3, 4, 5, or 6 inches apart, with the gap 15 extending the depth of the outlet cover 10. The gap 15 accommodates an electrical cord (not shown) to connect to the outlet and allows heat dissipation from the plug. A rubber gasket 15A with a slit 15B may be attached to the gap 15 to provide a more watertight seal when the outlet cover 10 is attached to the mounting bracket 30. The bottom sections 14A and 14B may be integrally formed with the side sections 18 and 20, respectively. Alternatively, the bottom section 14 may be omitted from the outlet cover 10.

Exposed edges of the upper section 12, lip portion 12A, bottom section 14, left-side section 18, and right-side section 20 may be rounded to minimize catch points that could damage an electrical cord passing through the gap 15.

A handle (not shown) may be attached to one or more surfaces of the outlet cover 10 to facilitate attachment of peripheral kitchen devices.

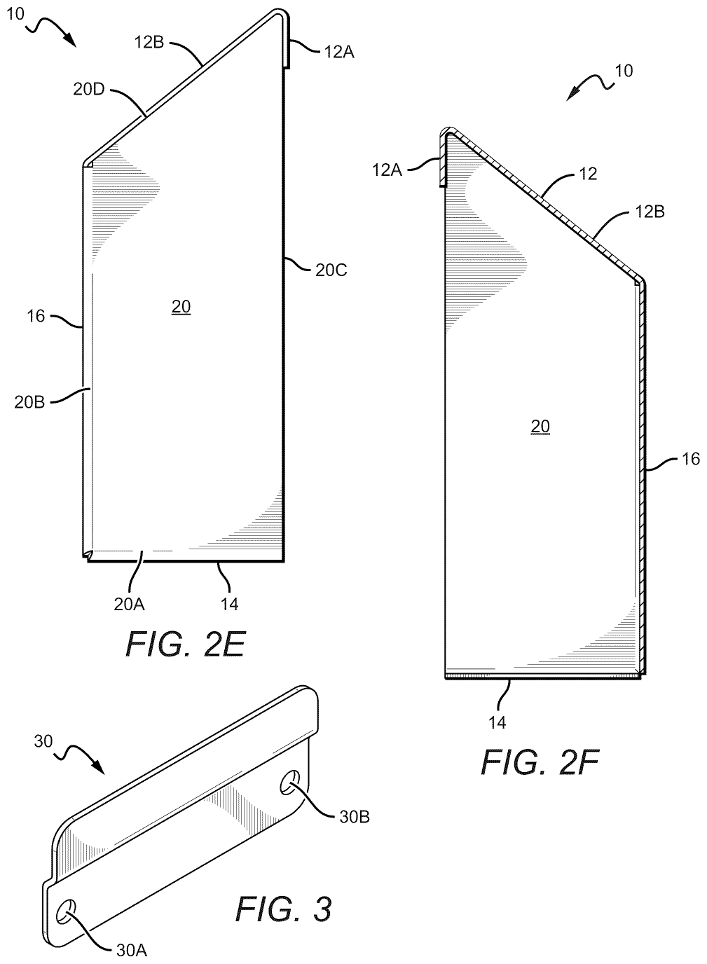

Referring to FIG. 3, the mounting bracket 30 is designed to be fixed to a mounting surface (e.g., a wall) adjacent to the electrical outlet. The bracket 30 includes screw holes 30A and 30B on opposing sides along its length, accommodating fasteners such as #10×¾ self-tapping 18/8 stainless steel sheet metal screws. Alternative attachment methods, such as nails, bolts, adhesives, or hook-and-loop fasteners, may be used. The bracket 30 is shorter than the lip portion 12A (e.g., 3.5 inches versus 4 inches) to ensure the outlet cover 10 sits flush or nearly flush with the wall, minimizing contaminant ingress. The bracket 30 features an offset portion (e.g., ⅛ inch) along its length to receive the lip portion 12A, enabling secure and removable attachment of the outlet cover 10 in a preferably watertight manner, with contaminants primarily entering via the gap 15, which can be mitigated by the gasket 15A.

One method for installing the outlet cover assembly 1 with the mounting bracket 30 includes the following steps, which may be modified or omitted as appropriate: (1) Turn off power to the electrical outlet at the main circuit breaker. (2) Verify the receptacle is de-energized. (3) With the existing plug (e.g., 50-amp plug) connected, position the outlet cover 10 over the plug, ensuring it is level and leaves approximately ¼ inch of clearance between the plug and the inside surface of the top section 12. (4) Mark a straight, level line on the wall along the top of the outlet cover 10. (5) Remove the outlet cover 10. (6) Align the mounting bracket 30 with the marked line and secure it to the wall using appropriate fasteners (e.g., two #10×¾ self-tapping screws). (7) Attach the outlet cover 10 to the mounting bracket 30 by engaging the lip portion 12A with the bracket 30 and pressing downward to achieve a snug fit (e.g., approximately 0.25 inches of engagement). (8) Restore power at the main circuit breaker.

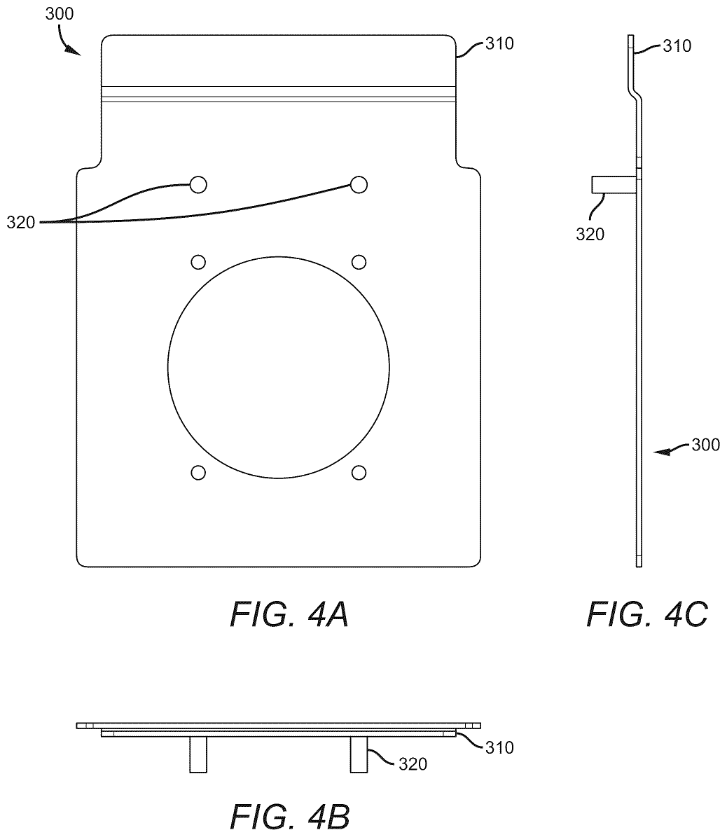

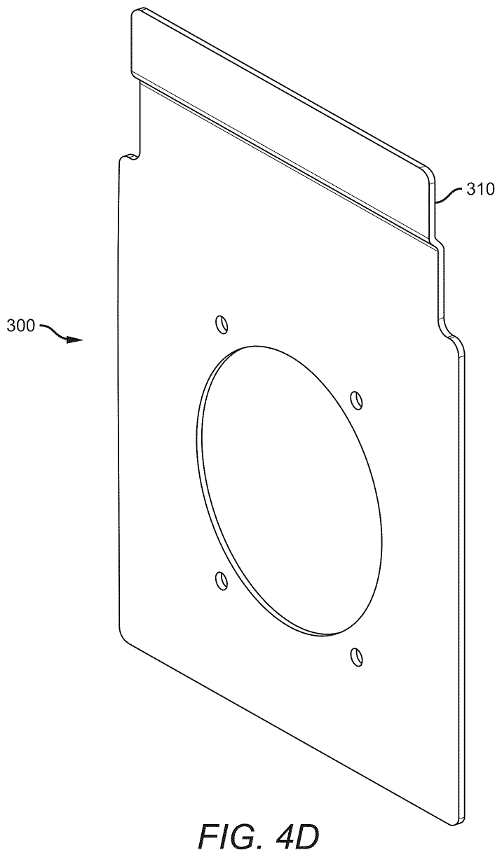

Referring to FIGS. 4A-4D, a faceplate 300 with an integrated mounting bracket 310 is configured for use with an outlet cover 10 over a standard electrical wall outlet (not shown). Unlike the previously disclosed wall-mounted bracket 30, which required separate anchoring into the wall surface, the faceplate 300 is designed to attach directly to the outlet receptacle using conventional fasteners (e.g., screws), thereby eliminating the need for wall penetration and reducing the risk of damaging hidden infrastructure such as wiring or plumbing.

The faceplate 300 is preferably fabricated from 16-gauge Type 304 stainless steel with a #3 brushed finish, offering durability and corrosion resistance suitable for demanding environments such as commercial kitchens. In one embodiment, the faceplate 300 has a vertical dimension that is shorter than the lip portion 12A of the outlet cover 10 (e.g., approximately 3.5 inches versus 4.0 inches), which facilitates a flush or near-flush installation against the wall surface while allowing the outlet cover to fully engage with the mounting bracket.

The integrated mounting bracket 310, visible in FIGS. 4B and 4D, is formed as an offset portion extending longitudinally across the faceplate 300. In one embodiment, the bracket 310 is offset from the faceplate surface by approximately 0.125 inches (⅛ inch) and is configured to receive the lip portion 12A of the outlet cover 10. This configuration enables secure, removable engagement of the outlet cover 10 with the faceplate 300, preferably in a watertight manner. A gasket 15A may be disposed between the outlet cover and the wall surface to minimize ingress of moisture, dust, grease, or other contaminants. The integrated design of the faceplate 300 and mounting bracket 310 thus replaces the earlier bracket 30 and provides a more streamlined, durable, and installation-friendly solution.

In certain embodiments, the faceplate 300 includes two safety posts 320, visible in FIGS. 4A and 4C, positioned above the receptacle opening and projecting outward from the front surface of the faceplate. Each safety post 320 comprises a welded stainless steel stud having a nominal diameter of approximately 0.188 inches and a projection length of approximately 0.500 inches. The posts are welded at a perpendicular angle (i.e., 90 degrees) to the faceplate surface and are spaced approximately 0.094 inches apart. The posts are located approximately 0.750 inches from the top edge of the faceplate 300.

The safety posts 320 serve multiple functions. They prevent the outlet cover 10 from contacting live plug prongs during installation or use, thereby enhancing electrical safety. They also act as spacers to ensure that the outlet cover 10 does not rest directly on the faceplate surface, which facilitates proper engagement with the integrated mounting bracket 310 and maintains the integrity of the gasket seal. The posts further provide lateral rigidity, helping to resist displacement or deformation caused by incidental contact or vibration.

Alternative configurations may include different numbers, dimensions, materials, or orientations of the safety posts 320, provided that such variations maintain sufficient structural rigidity and achieve the same safety and alignment objectives.

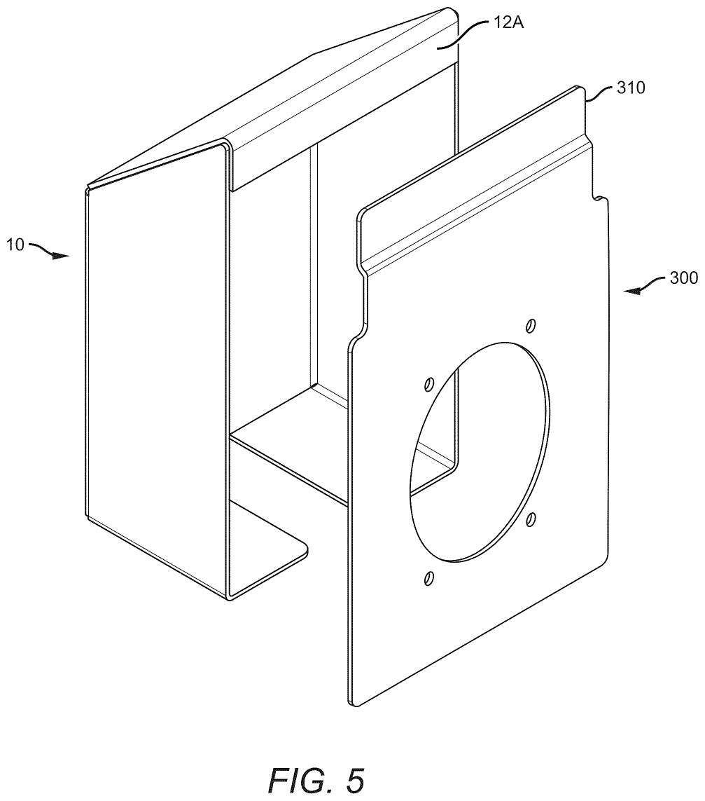

One method for installing the outlet cover assembly 1 using the faceplate 300 with integrated mounting bracket 310 includes the following steps, which may be modified or omitted as appropriate: (1) Turn off power to the electrical outlet at the main circuit breaker. (2) If necessary, remove the existing faceplate from the outlet receptacle. (3) Position the faceplate 300 over the outlet receptacle and secure it using one or more screws through the designated mounting holes. (4) Align the lip portion 12A of the outlet cover 10 with the integrated mounting bracket 310 and press downward until a snug fit is achieved (e.g., approximately 0.25 inches of engagement). (5) Restore power at the main circuit breaker. The embodiment shown in FIG. 5 demonstrates the alignment of the lip portion 12A with the integrated mounting bracket 310.

This method simplifies installation by eliminating wall anchoring and reducing the number of components required, while maintaining secure and protective engagement of the outlet cover 10.

The foregoing description of specific embodiments has been presented for purposes of illustration and description. It is not intended to be exhaustive or to limit the invention to the precise forms disclosed. Many modifications and variations are possible in light of the teachings herein without departing from the broader spirit and scope of the invention.

The embodiments were chosen and described to best explain the principles of the invention and its practical application, thereby enabling others skilled in the art to best utilize the invention in various embodiments and with various modifications as suited to the particular use contemplated. All such modifications and variations are within the scope of the invention as determined by the appended claims when interpreted in accordance with the breadth to which they are fairly, legally, and equitably entitled The features of the various embodiments described herein may be combined in any manner that is technically feasible, unless expressly stated otherwise. The words “preferably,” “preferred,” or “preferred embodiment” are non-exclusive and mean “preferably, but not limited to. ” Unless explicitly recited using the exact phrase “means for” (or “step for”) together with a corresponding function and without recitation of corresponding structure, material, or acts in support thereof, no claim limitation shall be interpreted under 35 U.S.C. § 112(f) (pre-AIA 35 U.S. C. § 112, sixth paragraph).

While the disclosed embodiments are particularly suited for commercial kitchens and food-service environments where protection of electrical outlets from contaminants is desired, the invention is not limited to these environments and may be used in any setting that would benefit from the disclosed features.

I claim:

1. An electrical outlet cover assembly comprising:
an outlet cover unit comprising an upper section with a lip portion, a front section, a left-side section, a right-side section, and an open end opposite the front section, the outlet cover unit configured to enclose an electrical plug inserted into an electrical receptacle; and
a faceplate unit comprising a planar body configured to be mounted to the electrical receptacle using one or more fasteners, and a mounting bracket integrally formed on a top side of the planar body, wherein
the mounting bracket comprises an offset portion extending along a lengthwise direction of the faceplate unit, the offset portion configured to releasably engage the lip portion of the outlet cover unit to securely and removably attach the outlet cover unit to the faceplate unit,
whereby the electrical cover unit and the faceplate unit together form a protective enclosure around the electrical plug to inhibit ingress of contaminants.

2. The electrical outlet cover assembly of claim 1, further comprising:
a pair of safety posts extending outward from a front surface of the faceplate unit, wherein
the safety posts are positioned above plug slots of the electrical receptacle when the faceplate unit is mounted, and
the safety posts are configured to prevent the outlet cover unit from contacting live plug prongs or resting on the front surface of the faceplate unit.

3. The electrical outlet cover of claim 2, wherein the safety posts are integrally formed with the faceplate unit.

4. The electrical outlet cover of claim 2, wherein the safety posts are affixed to the faceplate unit using mechanical fasteners or welds.

5. The electrical outlet cover of claim 2, wherein the safety posts are constructed from a non-conductive material to enhance electrical safety.

6. The electrical outlet cover of claim 1, further comprising a gasket or seal positioned between the plate and the wall surface to provide environmental protection. further comprising a gasket or seal positioned between the faceplate and a wall surface when the faceplate is mounted, the gasket or seal configured to provide environmental protection against contaminants such as grease or liquids.

7. The electrical outlet cover assembly of claim 1, wherein the outlet cover unit further comprises a bottom section with a gap configured to allow passage of an electrical cord, the gap including a rubber gasket with a slit to provide a substantially watertight seal around the electrical cord.

8. The electrical outlet cover assembly of claim 1, wherein the outlet cover unit is constructed from stainless steel, and the faceplate is dimensioned to fit standard single-or multi-gang electrical receptacle configurations.

9. A faceplate unit configured for use with an electrical outlet cover assembly, comprising:
a planar body configured to be mounted to the electrical receptacle using one or more fasteners; and
a mounting bracket integrally formed on the planar body, the mounting bracket comprising an offset portion extending along a lengthwise direction of the planar body,
wherein the offset portion is configured to engage a complementary structure to facilitate secure and removable attachment.

10. The faceplate unit of claim 9, wherein the planar body is constructed from stainless steel, aluminum, or a polymeric material selected for durability and corrosion resistance.

11. The faceplate unit of claim 9, further comprising a pair of safety posts extending outward from a front surface of the planar body, the safety posts positioned to prevent contact with live plug prongs and to maintain spacing from adjacent components.

12. The faceplate unit of claim 9, further comprising a gasket or seal positioned between the planar body and a wall surface when mounted, the gasket or seal configured to inhibit ingress of contaminants including grease, moisture, and liquids.

13. A method for installing an electrical outlet cover assembly to protect an electrical receptacle, the method comprising:
mounting a faceplate to an electrical receptacle, the faceplate comprising a planar body with an integrally formed mounting bracket having an offset portion extending along a lengthwise direction of the faceplate; and
attaching an outlet cover unit to the faceplate by engaging a lip portion of the outlet cover unit with the offset portion of the mounting bracket, the outlet cover unit comprising an upper section with the lip portion, a front section, a left-side section, a right-side section, and an open end opposite the front section, thereby forming a protective enclosure around an electrical plug inserted into the electrical receptacle.

14. The method of claim 13, wherein mounting the faceplate comprises securing the faceplate to the electrical receptacle using one or more screws.

15. The method of claim 13, further comprising passing an electrical cord through a gap in a bottom section of the outlet cover unit, the gap including a rubber gasket with a slit to provide a substantially watertight seal around the electrical cord.

16. The method of claim 13, wherein the faceplate comprises a pair of safety posts extending outward from a front surface of the planar body, positioned above plug slots of the electrical receptacle, and wherein attaching the outlet cover unit comprises aligning the outlet cover unit to avoid contact with the safety posts, ensuring proper engagement with the mounting bracket.

17. A method of installing a faceplate unit to an electrical receptacle, the method comprising:
positioning a faceplate unit over an electrical receptacle, the faceplate unit comprising a planar body and an integrally formed mounting bracket; and
securing the faceplate unit to the electrical receptacle using one or more fasteners inserted through mounting holes in the planar body.

18. The method of claim 17, wherein the faceplate unit comprises a safety post extending outward from a front surface.

19. The method of claim 18, further comprising aligning the safety posts above plug slots of the electrical receptacle during installation.

20. The method of claim 17, wherein the faceplate unit is secured using screws inserted through preformed mounting holes in the planar body.
